(19) United States
(12) Patent Application Publication
(10) Pub. No.: US 2015/0017788 A1
(43) Pub. Date: Jan. 15, 2015

(54) METHOD FOR MAKING SILICON-GERMANIUM ABSORBERS FOR THERMAL SENSORS

(71) Applicant: BAE Systems Information And Electronic Systems Integration Inc., Nashua, NH (US)

(72) Inventor: Vu A. Vu, Falls Church, VA (US)

(21) Appl. No.: 14/327,715

(22) Filed: Jul. 10, 2014

Related U.S. Application Data
(60) Provisional application No. 61/845,081, filed on Jul. 11, 2013.

(51) Int. Cl. H01L 21/02

(52) U.S. Cl. CPC H01L 21/02664; H01L 21/02532; H01L 21/02595
USPC 438/488

(57) ABSTRACT

A system and method for growing polycrystalline silicon-germanium film that includes mixing a GeH₄ gas and a SiH₄ gas to coat and grow polycrystalline silicon-germanium film on a silicon wafer. The GeH₄ gas and the SiH₄ gas are also heated and the pressure around the wafer is reduced to at least 2.5*10⁻³ mBar to produce the polycrystalline silicon-germanium film. The polycrystalline silicon-germanium film is then annealed to improve its resistivity.

### CROSS REFERENCE TO RELATED APPLICATION

This application claims priority from U.S. Provisional Application Ser. No. 61/845,081, filed Jul. 11, 2013; the disclosure of which is incorporated herein by reference.

### BACKGROUND OF THE INVENTION

1. Field of Invention

The current invention relates generally to apparatus, systems and methods for growing materials. More particularly, the apparatus, systems and methods relate to using chemical vapour deposition to grow materials. Specifically, the apparatus, systems and methods provide for growing polycrystalline silicon-germanium.

2. Description of Related Art

Typical materials used for manufacturing uncooled microbolometer imagers or thermal detectors are vanadium oxide and platinum. A microbolometer is a specific type of bolometer used as a detector in a thermal camera. Infrared radiation with wavelengths between 7.5-14 μm strikes the detector material, heating it, and thus changing its electrical resistance. This resistance change is measured and processed into temperatures which can be used to create an image. Unlike other types of infrared detecting equipment, microbolometers do not require cooling.

Vanadium oxide is not practical for mass production due to difficulties in process control and high manufacturing cost. Platinum has a low temperature coefficient of resistance (TCR), and its resistivity range is not useful for many applications. The temperature coefficient of resistance, or TCR, is a key parameter used to characterize a resistor. The TCR defines the change in resistance as a function of the ambient temperature. The temperature coefficient of resistance is calculated as follows:

$$TCR = - \frac{{E}_{A}}{{kT}^{2}}$$

$$or$$

$$TCR = \frac{1}{{R}_{0}} \frac{Δ R}{Δ T}$$

Where E_{A} is activation energy, k the Boltzmann constant, R₀ is resistor of initial value, T is absolute temperature (K), ΔT is change of temperature, and ΔR is change of the resistivity as a result of the change of temperature ΔT.

Amorphous silicon, amorphous silicon-germanium, or poly silicon-germanium are desirable materials for manufacturing uncooled microbolometer imagers or thermal detectors, but most growth techniques do not meet the technical requirements due to its extremely high resistivity and low TCR. What is needed is a better way to manufacturing uncooled microbolometer imagers or thermal detectors.

### SUMMARY

One aspect of an embodiment of the invention is a method for growing polycrystalline silicon-germanium (p-SiGe) using UHV-CVD systems and then modifying the grown films for achieving desired resistivity. A p-SiGe film is grown on an oxide or nitride layer, depending on the application. The oxide or nitride film may have been previously grown on a silicon substrate or on a waveguide, depending on the application. After the growth, an anneal process is performed to bring the resistivity into the operation range for which the thermal detector is designed. Detectors or arrays of pixels are then defined by a typical photolithography process, followed by a plasma etch process. Detectors or arrays of pixels also can be grown in open windows formed prior to the growth, surrounded by dielectric materials.

In another aspect another embodiment may be a method for growing polycrystalline silicon-germanium. The method begins by mixing a GeH₄ gas and a SiH₄ gas to coat and grow polycrystalline silicon-germanium film on a silicon wafer. The GeH₄ gas and the SiH₄ gas is also heated and the pressure around the wafer is reduced to at least 2.5*10⁻³ mBar to produce the polycrystalline silicon-germanium film. The polycrystalline silicon-germanium film is then annealed to improve its resistivity.

### BRIEF DESCRIPTION OF SEVERAL VIEWS OF THE DRAWINGS

One or more preferred embodiments that illustrate the best mode(s) are set forth in the drawings and in the following description. The appended claims particularly and distinctly point out and set forth the invention.

The accompanying drawings, which are incorporated in and constitute a part of the specification, illustrate various example methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates a preferred embodiment of a silicon wafer onto which two oxide layers, another silicon layer and an upper nitride layer have been grown and onto which polycrystalline silicon-germanium is later grown.

FIG. 2 illustrates the preferred embodiment of a silicon wafer of FIG. 1 after a thin film of polycrystalline silicon-germanium has been grown on it.

FIG. 3 illustrates the preferred embodiment of the silicon wafer of FIG. 2 with photoresist deposited on it.

FIG. 4 illustrates the preferred embodiment of the silicon wafer of FIG. 3 with the photoresist removed after wet cleaning and with polycrystalline silicon-germanium thermal absorbers formed on it.

Similar numbers refer to similar parts throughout the drawings.

### DETAILED DESCRIPTION

In summary, the preferred embodiment creates polycrystalline silicon-germanium based pixels and/or waveguides that have a well-known resistance and TCR and that can be used to create very accurate thermal sensors such as uncooled microbolometer imagers and/or thermal detectors and the like.

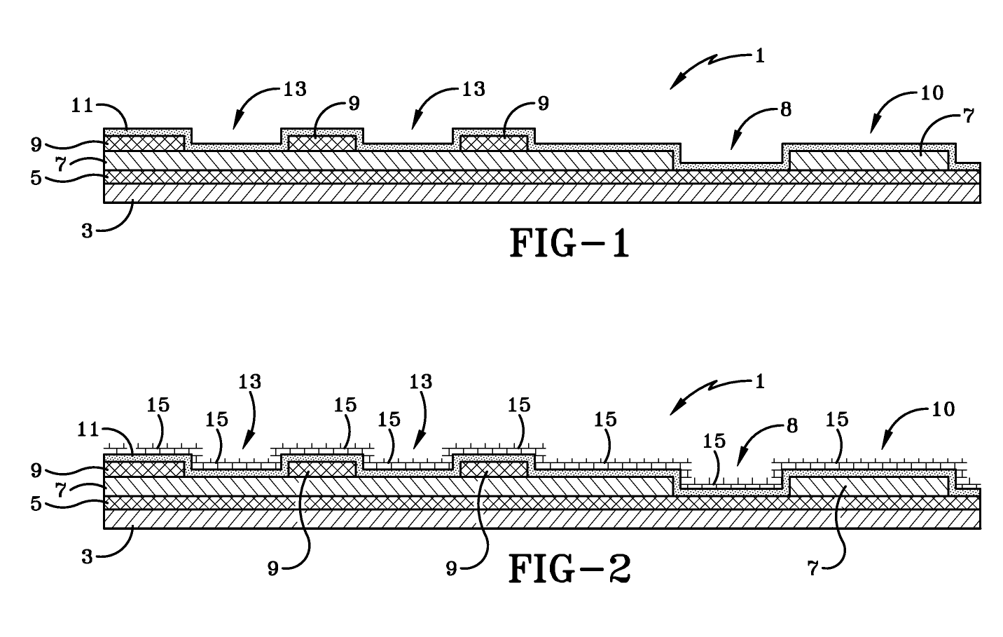

FIG. 1 illustrates an example starting dielectric layer with silicon, nitride and oxide layers. As discussed below, a preferred embodiment method uses polycrystalline silicon-germanium to fabricate silicon waveguides and/or an array of pixels (e.g., thermal sensors) or other openings onto the structures of FIG. 1. As illustrated, the dielectric layer starts out as a layer of silicon 3. Next, a layer of oxide 5 is deposited on top of the first layer of silicon 3. A second layer of silicon 7 is added on top of the first oxide layer 5. This creates a silicon wafer 1. Some areas of this silicon layer 7 can be left open (or later removed) to form box(es) 8 next to a waveguide 10 that is being formed. A second layer of oxide 9 is formed on the second layer of silicon 7. In general, this second layer of oxide 9 is deposited at areas where pixels 13 (e.g., thermal sensors) are being formed. A layer of nitride 11 is then deposited on top of the wafer 1. This layer of nitride 11 is used in forming the pixels 13 as well as a waveguide 10. Both the waveguide 10 and the pixels 13 can be used to create thermal sensors. As understood by those of ordinary skill in this art these various layers can be grown using one or more of: a dielectric layer of low pressure chemical vapor deposition (LPCVD) nitride, plasma enhanced chemical vapor deposition (PECVD) nitride, thermal oxide, PECVD oxide, tetraethoxysilane (TEOS), and/or high-density plasma (HDP).

Next, the preferred embodiment of a method for growing polycrystalline silicon-germanium grows a p-SiGe film 15, as illustrated in FIG. 2, in an ultra-high vacuum-chemical vapor deposition (UHV-CVD) reactor to produce the p-SiGe film on top of the structure illustrated in FIG. 1. In other embodiments, this film 15 can be grown with a quartz reactor tube kept at high temperature as the batch of the substrates are loaded into the tube. This guarantees good temperature uniformity. In the preferred embodiment, wafer temperatures of about 550° C. to 600° C. are used for deposition. At these temperatures, the gaseous precursor reacts with the silicon wafer surface and deposition occurs.

The UHV-CVD system is a batch type production system which ensures high throughput. High uniformity over the whole batch is achieved with a low processing temperature range. This range is restricted by the limitation of hydrogen desorption from the wafer surface. In the preferred embodiment, the base pressure of the system is about 10⁻⁹ mBar. This low pressure ensures control over the residual gases and prevents the incorporation of contamination during the deposition process. For the deposition, the gas flows of the precursors (silane, germane and dopant gases) are initiated, resulting in a process pressure of about 10⁻⁴ mBar range.

In some embodiments, an Inficon residual gas analysis (RGA) instrument, capable of measuring up to 200 atomic mass units (amu) over the partial pressure range of 10⁻⁵ to 10⁻¹³ Torr, can be present on the process chamber. The RGA has a separate set of pumps attached to it, and is connected to the main chamber through a gate valve in parallel with a variable orifice. This allows for differential pumping of the RGA chamber and sampling of the deposition gases during growth.

The inventor has grown silicon-germanium and germanium 15 using silane (SiH₄) and germane (GeH₄). Hydrides were used as precursor gases because hydrogen scavenges oxygen which reduces oxide inclusions in the film. During an epitaxial growth process, silane or germane is decomposed at the wafer surface into silicon (layer growth) and the hydrogen is pumped off. Growth rates depend on gas flow, substrate temperature, process pressure, process time and precursor.

The preferred embodiment has grown polycrystalline silicon-germanium 15 with thicknesses in the range of 100 nm to using an UHV-CVD system and using a gas mixture of 45% germane (GeH₄) and 55% silane (SiH₄) at 2.5°10⁻³ mBar at a temperature range of 550° C. or 600° C. After growth, the TCR is measured as 2%/° C. to 3%/° C. and the resistivity was measured as 20 KOhm/sq to 100 KOhm/sq at room temperature. This TCR is very high and meets the requirement for most microbolometer applications. However, the resistivity is still high. Some circuit designs may require a lower range of resistivity to improve signal to noise performance. Thus the preferred embodiment can include an anneal process with oxygen to bring the resistivity into the operation range for which the thermal detector is designed. However, the temperature coefficient of resistance (TCR) is reduced after being annealed. The invention balances the tradeoff between high TCR and low resistivity at room temperature to meet the requirement for both parameters for particular applications.

The wafers with grown silicon-germanium films 15 are annealed with either nitrogen or oxygen in an oxidation furnace at 800° C. to 900° C. In the preferred embodiment, the anneal processes is performed in a horizontal oxidation furnace. However, the anneal process can be done in any type of quartz tube capable of supplying oxygen and nitrogen gases and controlling temperature at ±5°. The wafers are loaded in to the tube at 700° C., ramped up to the desired temperature in nitrogen at five degrees per minute increasement in 5 slpm of nitrogen, stabilized in nitrogen at the desired temperature for 30 minutes, annealed in 5 slpm undiluted oxygen for a desired anneal time, then ramped down in nitrogen ambient at 5° per minute to 700° C. and unloaded.

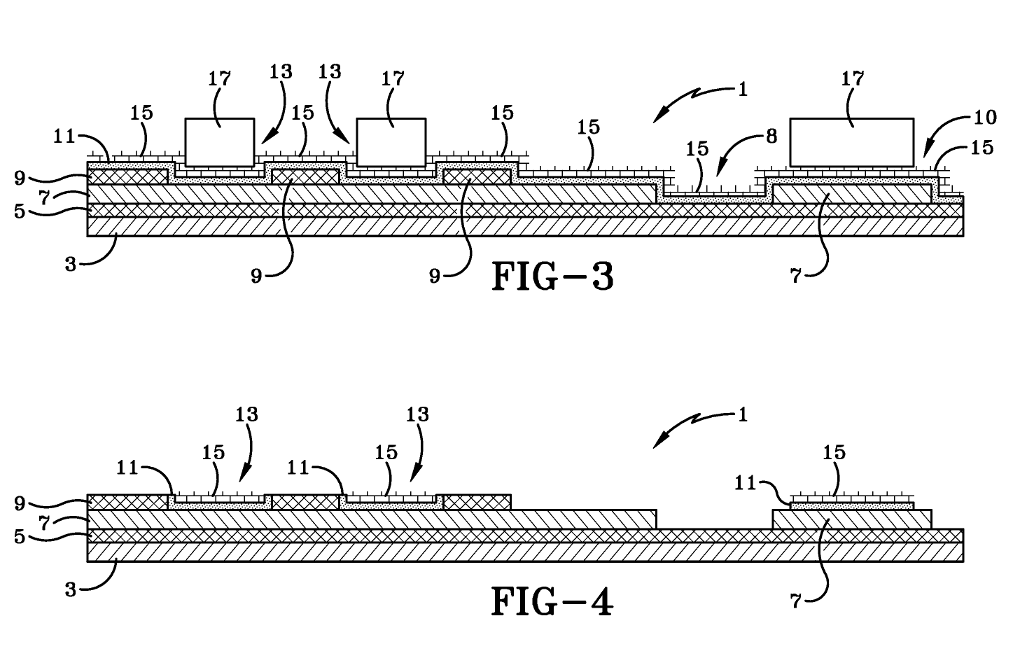

After being annealed, the TCR may reduce by as much as 50%, and resistivity could decrease down to 1/10 of the original value. Thermal detectors or pixel array 13 are defined by typical photography process as illustrated best in FIGS. 3 and 4. FIG. 3 illustrates where a photoresist material 17 is deposited to form the pixel array and/or waveguide. A plasma etch process with hydrogen bromide (HBr) and chlorine (Cl₂) forms the thermal absorber (e.g., pixels 13 and/or waveguide 10). The photoresist 17 is then removed by a plasma ASH process followed by a wet clean with sulfuric acid and hydrogen peroxide strip that is illustrated in FIG. 4.

The preferred embodiment of creating polycrystalline silicon-germanium based pixels 13 and/or waveguides that have a well-known resistance and TCR that can be used to create very accurate thermal sensors such as uncooled microbolometer imagers or thermal detectors and the like.

In summary, the preferred embodiment grows about 200 nm of polycrystalline silicon-germanium using 45% germane (GeH₄) and 55% silane (SiH₄) at 2.5*10⁻³ mBar at 550° C. to achieve a resistivity of about 50 KOhm/sq at room temperature and TCR equal to about 2.3%/° C.

Another embodiment grows about 200 nm of polycrystalline silicon-germanium using 45% germane (GeH₄) and 55% silane (SiH₄) at 2.5*10⁻³ mBar at 550° C. for getting resistivity of about 50 KOhm/sq at room temperature and TCR equal to about 2.3%/° C. This embodiment, further, anneals the film with oxygen ambient at 800° C. in 30 minutes to achieve resistivity of 25 KOhm/sq at room temperature and TCR equal to 1.6%/° C.

A third embodiment grows about 200 nm of polycrystalline silicon-germanium using 45% germane (GeH₄) and 55% silane (SiH₄) at 2.5*10⁻³ mBar at 550° C. for getting resistivity of about 50 KOhm/sq at room temperature and TCR equal to about 2.3%/° C. This embodiment, further anneals the film with oxygen ambient at about 900° C. in 10 minutes to achieve resistivity of about 8 KOhm/sq at room temperature and TCR equal to about 1.2%/° C. The resistivity changes from about 20 KOhm/sq to about 3 KOhm/sq as temperature increases from about −40° C. to 100° C.

A fourth embodiment grows about 200 nm of polycrystalline silicon-germanium using 45% germane (GeH₄) and 55% silane (SiH₄) at about 2.5*10⁻³ mBar at about 600° C. for getting resistivity of about 70 KOhm/sq at room temperature and TCR equal to about 3.0%/° C.

A fifth embodiment grows about 200 nm of polycrystalline silicon-germanium using 45% germane (GeH₄) and 55% silane (SiH₄) at 2.5°10⁻³ mBar at 600° C. for getting resistivity of 70 KOhm/sq at room temperature and TCR equal to 3.0%/° C. This embodiment further anneals the film with oxygen ambient at about 800° C. in about 30 minutes to achieve resistivity of about 40 KOhm/sq at room temperature and TCR equal to about 2.5%/° C.

A sixth embodiment grows about 200 nm of polycrystalline silicon-germanium using 45% germane (GeH₄) and 55% silane (SiH₄) at 2.5*10⁻³ about mBar at 600° C. for getting resistivity of about 70 KOhm/sq at room temperature and TCR equal to about 3.0%/° C. This embodiment further anneals the film with oxygen ambient at about 900° C. in about 10 minutes to achieve resistivity of about 10 KOhm/sq at room temperature and TCR equal to about 1.5%/° C. The resistivity changes from 25 about KOhm/sq to 4 about KOhm/sq as temperature increases from about −40° C. to about 100° C.

In the foregoing description, certain terms have been used for brevity, clearness, and understanding. No unnecessary limitations are to be implied therefrom beyond the requirement of the prior art because such terms are used for descriptive purposes and are intended to be broadly construed. Therefore, the invention is not limited to the specific details, the representative embodiments, and illustrative examples shown and described. Thus, this application is intended to embrace alterations, modifications, and variations that fall within the scope of the appended claims.

Moreover, the description and illustration of the invention is an example and the invention is not limited to the exact details shown or described. References to “the preferred embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in the preferred embodiment” does not necessarily refer to the same embodiment, though it may.

What is claimed is:

1. A method of growing polycrystalline silicon-germanium film comprising:
mixing a GeH₄ gas and a SiH₄ gas to coat and grow the polycrystalline silicon-germanium film on a dielectric layer;
heating the GeH₄ gas and a SiH₄ gas;
reducing pressure around the dielectric layer to at least 2.5*10⁻³ mBar to produce polycrystalline silicon-germanium film; and
annealing the polycrystalline silicon-germanium film.

2. The method of claim 1 wherein the mixing the GeH₄ gas and the SiH₄ gas further comprises:
mixing about 45% GeH₄ with about 55% SiH₄.

3. The method of claim 1 wherein the heating the GeH₄ gas and a SiH₄ gas further comprises:
heating the GeH₄ gas and a SiH₄ gas to about 550 degrees Celsius.

4. The method of claim 1 wherein the heating the GeH₄ gas and a SiH₄ gas further comprises:
heating the GeH₄ gas and a SiH₄ gas to at least 500 degrees Celsius.

5. The method of claim 1 wherein the annealing further comprises:
annealing the polycrystalline silicon-germanium film with oxygen at about 800° C.

6. The method of claim 5 wherein the annealing further comprises:
annealing the polycrystalline silicon-germanium film with oxygen for at least 10 minutes.

7. The method of claim 1 wherein the annealing further comprises:
annealing the polycrystalline silicon-germanium film with oxygen above 750° C. for at least eight minutes.

8. The method of claim 1 wherein the silicon-germanium film has a resistivity of between 3K Ohm/sq to 40K Ohm/sq as temperature changes respectively from −40° C. to 100° C.

9. The method of claim 1 wherein the mixing a GeH₄ gas and the SiH₄ gas further comprises:
mixing the GeH₄ gas and the SiH₄ gas in a quartz reactor tube.

10. The method of claim 1 wherein the mixing a GeH₄ gas and the SiH₄ gas occurs at a base pressure of about 10⁻⁹ mBar.

11. The method of claim 1 wherein the annealing further comprises:
annealing the dielectric layer grown silicon-germanium films with one of the group of: nitrogen and oxygen in an oxidation furnace between 800° C. and 900° C.

12. The method of claim 1 wherein the annealing further comprises:
annealing the polycrystalline silicon-germanium film in a horizontal oxidation furnace.

13. The method of claim 1 wherein the annealing further comprises:
annealing the polycrystalline silicon-germanium film with at least one of the group of: oxygen and nitrogen.

14. The method of claim 1 further comprising:
using hydrides as precursor gases to scavenge oxygen to reduce oxide inclusions in the polycrystalline silicon-germanium film.

15. The method of claim 1 further comprising:
using a residual gas analysis (RGA) instrument for differential pumping of the RGA chamber and for the sampling of the deposition gases during growth.

16. The method of growing polycrystalline silicon-germanium film comprising:
providing between 40 and 50 percent of Germanium (Ge) gas and between 50 to 60 percent of silicon (Si) gas to a silicon wafer;
heating the Ge and Si gasses to at least 500° C.;
reducing pressure around the silicon wafer to at least 2.0*10⁻³ mBar to produce the polycrystalline silicon-germanium film; and
annealing the polycrystalline silicon-germanium film with oxygen for at least 750° C. for at least 8 minutes.

17. The method of growing polycrystalline silicon-germanium film of claim 16 wherein the Ge gas is GeH₄ and the Si gas is SiH₄.

18. The method of growing polycrystalline silicon-germanium film of claim 16 further comprising:
mixing the Ge gas and the Si gas in a quartz reactor tube.

19. The method of growing polycrystalline silicon-germanium film of claim 16 wherein the providing between 40 and 50 percent of the Ge gas and between 50 to 60 percent of the Si gas to the silicon wafer further comprises:
providing the Ge gas and the Si gas to an ultra-high vacuum-chemical vapor deposition (UHV-CVD) reactor.

20. The method of growing polycrystalline silicon-germanium film of claim 16 wherein the polycrystalline silicon-germanium film has a resistivity of between 3K Ohm/sq to 40K Ohm/sq as temperature respectively changes from −40° C. to 100° C.
